(19) United States
(12) Patent Application Publication
(10) Pub. No.: US 2011/0156528 A1
(43) Pub. Date: Jun. 30, 2011

(54) MICRO ACTUATOR, MICRO ACTUATOR SYSTEM, AND METHOD FOR FABRICATING MICRO ACTUATOR

(76) Inventors: Chien-Chong Hong, Hsinchu County (TW); Sheng-Chin Su, Taichung County (TW)

(21) Appl. No.: 12/868,083

(22) Filed: Aug. 25, 2010

(30) Foreign Application Priority Data
Dec. 30, 2009 (TW) 098145777

(51) Int. Cl. H02N 11/00; B81B 3/00; B05D 1/02; B05D 1/36

(52) U.S. Cl. 310/300; 427/427; 427/402; 977/742; 977/962; 977/752; 977/890

(57) ABSTRACT

A micro actuator system includes a micro actuator and a light beam generator. The micro actuator includes a substrate, a cantilever beam, and a carbon nano-tube layer. The cantilever beam has a connection portion connected to the substrate, and the carbon nano-tube layer is disposed on the cantilever beam in a spray deposition technique. When the light beam generator generates a light beam for irradiating the carbon nano-tube layer on the connection portion of the cantilever beam, the carbon nano-tube layer drives the cantilever beam to be deformed towards a first direction.

### CROSS-REFERENCE TO RELATED APPLICATION

This application claims the benefit of Taiwan Patent Application No. 098145777, filed on Dec. 30, 2009, which is hereby incorporated by reference for all purposes as if fully set forth herein.

### BACKGROUND OF THE INVENTION

1. Field of Invention

The invention relates to a micro actuator, a micro actuator system, and a method for fabricating the micro actuator, and more particularly to a micro actuator driven by optical energy, a micro actuator system, and a method for fabricating the micro actuator.

2. Related Art

An actuator is a device capable of converting other forms of energy to mechanical energy. The conventional actuator is configured to convert electric energy to mechanical energy, that is, the actuator may receive an electric control signal for performing mechanical operations. The actuator may be used as a passive device of automatic response, and thus is widely applied to various fields, thereby it become an indispensable technology.

With the developing of microelectromechanics and nano technology, various existing technologies are currently developed towards miniaturization, such that whether the actuator can be successfully miniaturized becomes an important topic. A conventional electric actuating device, for example, an electrostatic or piezoelectric actuating device, transfers electric control signals through wire connection. Although the electric actuating manner is advantageous in having a low voltage and a high actuating frequency, the wires increase the complexity of the process, which is adverse to the miniaturization of the actuating system. In addition, although the electric actuating manner is advantageous in having wide applications, low power consumption, and high manipulation precision, the electric actuating manner needs to be manipulated through a current, and thus is affected by a magnetic field; the electromagnetic effect is greater in small-sized actuators.

In optical actuation schemes, the actuator is driven by optical energy instead of electric energy to perform mechanical operations, and the most distinctive feature is that an optical actuating system does not need wires for driving, so that non-contact and remote control is realized. Since the optical actuation does not need to drive the actuator through wire connection, the process is relatively simple, and suitable for the miniaturized actuator. Meanwhile, the optical actuation may also prevent interference of the electromagnetic effect. However, as compared with the electric actuation that is capable of directly converting the electric energy to the mechanical energy, the optical actuating manner of the prior art needs to first convert the optical energy to other forms of energy, for example, thermal energy or electric energy, and then to the mechanical energy, so that the conversion efficiency from the optical energy to the mechanical energy is low, and a large amount of energy is wasted.

The carbon nano-tube, having excellent physical and chemical properties and a quite stable structure, is regarded as a new nano material of the 21^{st} century. In the prior art, the carbon nano-tube is used as an actuating device, which may have both photoelectric and photothermal actuating mechanisms, so that the energy conversion efficiency can be improved with an optical actuating device made of the carbon nano-tube. In addition, the carbon nano-tube has a rather small size, which is advantageous to the miniaturization of the actuator.

For the actuator made of the carbon nano-tube, a carbon nano-tube layer is usually grown on a structure like a cantilever beam. Generally, the carbon nano-tube has two growth manners, i.e., thermal growth and plasma assisted growth, and the environment required by the two manners is rigorous and is not suitable for a cantilever beam with a weak structure. For example, in thermal growth, the carbon nano-tube needs to be produced at a high temperature of at least hundreds of degrees; while in plasma assisted growth, a plasma is used to impact a base material to assist generating the carbon nano-tube, so that the carbon nano-tube layer can be grown only if the cantilever beam has the characteristics of being high temperature resistant and plasma impact resistant, but the characteristics are adverse to mechanical operations, such as bending and other deformations.

### SUMMARY OF THE INVENTION

The invention is directed to a new type of micro actuator, capable of solving the above problems.

In an embodiment, a micro actuator is provided, which includes a substrate, a cantilever beam, and a carbon nano-tube layer disposed on the cantilever beam. The cantilever beam has a connection portion connected to the substrate, and the carbon nano-tube layer is disposed on the cantilever beam in a spray deposition technique.

The invention is also directed to a new type of micro actuator system, capable of solving the above problems.

In an embodiment, a micro actuator system is provided, which includes a micro actuator and a light beam generator. The micro actuator includes a substrate, a cantilever beam, and a carbon nano-tube layer disposed on the cantilever beam. The cantilever beam has a connection portion connected to the substrate and is suspended on the substrate, and the carbon nano-tube layer is disposed on the cantilever beam in a spray deposition technique.

In this embodiment, the light beam generator generates a light beam for irradiating the connection portion of the cantilever beam, and when the light beam irradiates the carbon nano-tube layer on the connection portion of the cantilever beam, the carbon nano-tube layer drives the cantilever beam to be deformed towards a first direction.

The invention is further directed to a method for fabricating a micro actuator, capable of solving the above problems.

In an embodiment, a method for fabricating a micro actuator is provided, which includes the following steps. Firstly, a substrate is fabricated. Then, a cantilever beam is formed on the substrate. Finally, a carbon nano-tube layer is formed on the cantilever beam in a spray deposition technique.

The efficacies and spirit of the invention will be further illustrated below with the accompanying drawings.

### BRIEF DESCRIPTION OF THE DRAWINGS

The invention will become more fully understood from the detailed description given herein below for illustration only, and thus are not limitative of the invention, and wherein:

FIG. 1 is a schematic view of a micro actuator system according to an embodiment of the invention;

FIG. 2 is a schematic partial view in which a light beam generator of FIG. 1 generates a light beam for irradiating a connection portion of a cantilever beam;

FIG. 3 is a schematic view of a spraying system that forms a carbon nano-tube layer on a cantilever beam in a spray deposition technique;

FIG. 4 is a flow chart of a method for fabricating a micro actuator according to another embodiment of the invention;

FIG. 5A is a flow chart of a method for fabricating a micro actuator according to another embodiment of the invention;

FIG. 5B is a schematic view of fabricating a micro actuator by using the method for fabricating the micro actuator in FIG. 5A; and

FIG. 6 is a flow chart of fabricating a micro actuator according to another embodiment of the invention.

### DETAILED DESCRIPTION OF THE INVENTION

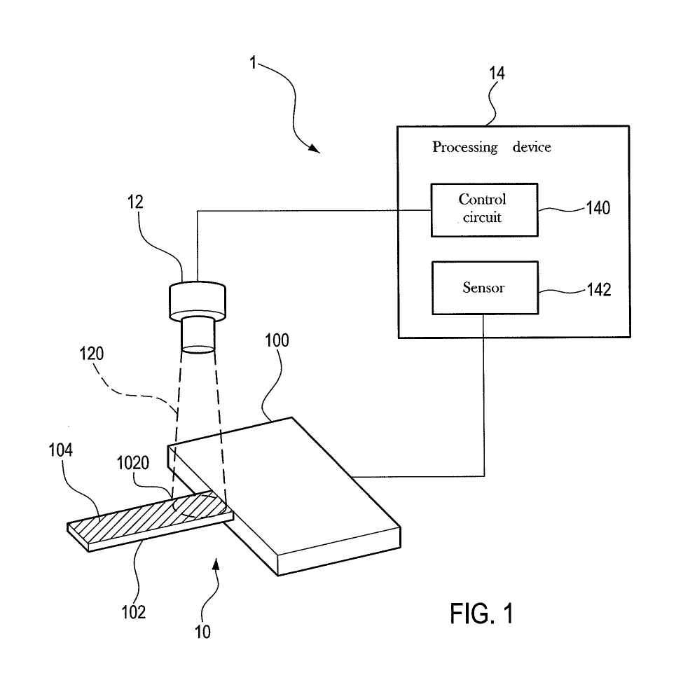

FIG. 1 is a schematic view of a micro actuator system 1 according to an embodiment of the invention. As shown in FIG. 1, the micro actuator system 1 includes an actuator 10 and a light beam generator 12, in which the light beam generator 12 may generate a light beam 120 for irradiating the micro actuator. In practices, the light beam generator 12 may be an ultraviolet laser generator or an infrared laser generator, so as to generate an ultraviolet laser or an infrared laser for irradiating the actuator 10.

In this embodiment, the actuator 10 includes a substrate 100 and a cantilever beam 102. The cantilever beam 102 has a connection portion 1020 connected to the substrate 100, and the cantilever beam 102 is suspended in the air. A carbon nano-tube layer 104 is disposed on the cantilever beam 102 in a spray deposition technique.

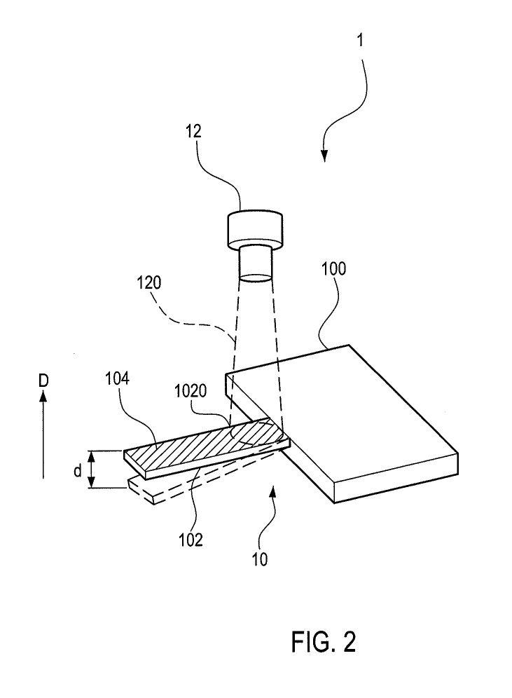

As shown in FIG. 1, the light beam 120 generated by the light beam generator 12 irradiates the connection portion 1020 of the cantilever beam 102, the light beam 120 is absorbed by the carbon nano-tube layer 104 on the connection portion 1020, and the carbon nano-tube layer 104 converts optical energy to electric energy and thermal energy, such that the cantilever beam 102 is driven by the carbon nano-tube layer 104 to generate a curling deformation. FIG. 2 is a schematic partial view in which the light beam generator 12 of FIG. 1 generates the light beam 120 for irradiating the connection portion 1020 of the cantilever beam 102. As shown in FIG. 2, the cantilever beam 102 irradiated by the light beam 120 generates the curling deformation towards a first direction D; therefore, tip portions of the cantilever beam 102 (indicated by dashed lines in FIG. 2) before being irradiated by the light beam 120 and the cantilever beam 102 irradiated by the light beam 120 are spaced by a distance d. It should be noted that the distance d changes according to irradiation time and intensity of the light beam 120. For example, the longer the irradiation time of the light beam 120 with certain energy intensity is, the larger the distance d will be. In another aspect, if the irradiation time of the light beam 120 is the same, when the light beam 120 with higher energy intensity irradiates the cantilever beam 102, the distance d will be larger.

When the light beam 120 stops irradiating the cantilever beam 102, the cantilever beam 102 may be restored to an original position, such that the cantilever beam 102 may show a periodic motion behavior under the irradiation of a periodic pulsed light.

Referring to FIG. 1, the micro actuator system 1 further includes a control circuit 140 connected to the light beam generator 12, so as to control the light beam 120 generated by the control light beam generator 12. For example, in practices, the control circuit 140 controls the light beam generator 12 to generate a continuous light beam or a pulsed light beam, in which the control circuit 140 may also control the irradiation time of the light beam or the frequency of the pulsed light, and event control the energy intensity of the light beam. In addition, the micro actuator system 1 further includes a sensor 142 for sensing a displacement of the cantilever beam 102, and in practices, the sensor 142 may be a charge-coupled device (CCD) sensor, for calculating a displacement of the cantilever beam 102 with real images. In this embodiment, the control circuit 140 and the sensor 142 may be disposed in a processing device 14 and managed by the processing device 14, and the processing device 14 is practically a computer or other data processing devices.

In this embodiment, the cantilever beam 102 is made of, but not limited to, a polymer material. In practices, the cantilever beam made of the polymer material is unable to stand under a high temperature, and its structure is not as firm as a cantilever beam made of metal, so that the carbon nano-tube layer cannot be disposed on the cantilever beam made of the polymer material in a common thermal growth or plasma assisted growth manner.

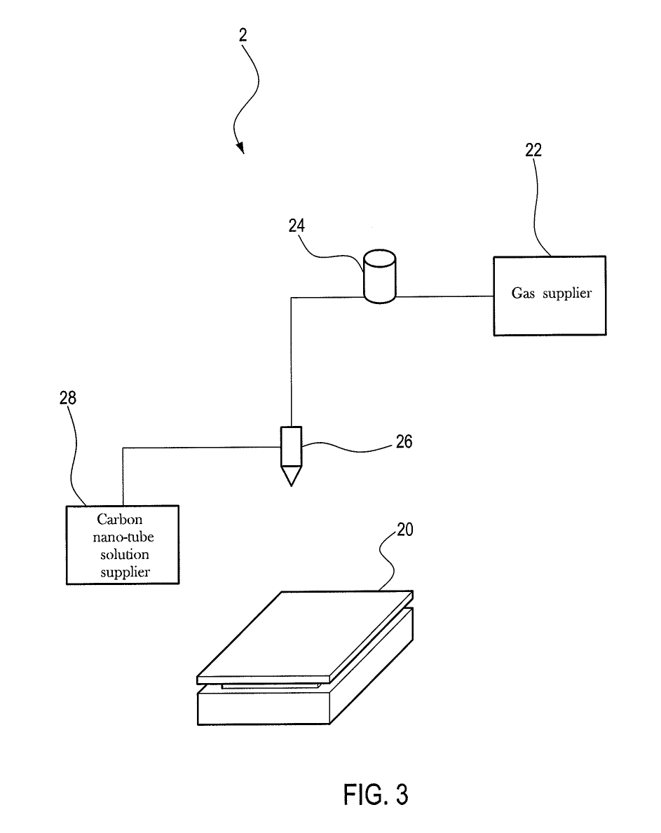

In view of the above, the carbon nano-tube layer 104 of this embodiment is disposed on the cantilever beam 102 in the spray deposition technique. FIG. 3 is a schematic view of a spraying system 2 that forms the carbon nano-tube layer on the cantilever beam in the spray deposition technique. As shown in FIG. 3, the spraying system 2 includes a hot plate 20, a gas supplier 22, an electromagnetic valve 24, a nozzle 26, and a carbon nano-tube solution supplier 28.

The nozzle 26 is connected to the carbon nano-tube solution supplier 28 and the gas supplier 22, so as to accept a carbon nano-tube solution and an injection gas. The electromagnetic valve 24 is disposed between the gas supplier 22 and the nozzle 26, so as to control the speed and time of spraying the carbon nano-tube of the nozzle 26 towards the hot plate 20. The actuator 10 may be disposed on the hot plate 20, and thus the cantilever beam 102 of the actuator 10 may accept the nozzle 26 to spray the carbon nano-tube thereon to form the carbon nano-tube layer 104. It should be noted that the hot plate 20 maintains the actuator at a low temperature or room temperature, so that in this system, the actuator 10 may not enter a high temperature process or a plasma assisted process.

The carbon nano-tube solution used by the spraying system 2 is prepared by dissolving a multi-layer carbon nano-tube in an ethanol solvent, and thus the carbon nano-tube layer 104 is formed by the multi-layer carbon nano-tube. However, the invention is not limited thereto, that is, the carbon nano-tube layer 104 may be formed by a single-layer carbon nano-tube, or by mixing a single-layer carbon nano-tube and a multi-layer carbon nano-tube. In addition, according to spraying times, the thickness of the carbon nano-tube layer 104 may be adjusted. In practices, after one time of spraying, the thickness of the carbon nano-tube layer is increased by 100 nanometers, and the thickness of the carbon nano-tube layer 104 may be up to 15 micrometers.

To sum up, through the spray deposition technique, the carbon nano-tube layer may be grown on the cantilever beam of the actuator at a low temperature or room temperature, such that the spray deposition technique for spraying the carbon nano-tube is applicable to a thermolabile or weak structure, for example, the cantilever beam made of a polymer material. It should be noted that the actuator of the invention may include other actuating devices, and is not limited to the cantilever beam. For example, the carbon nano-tube layer may be disposed on the structure similar to a spring through the spray deposition technique.

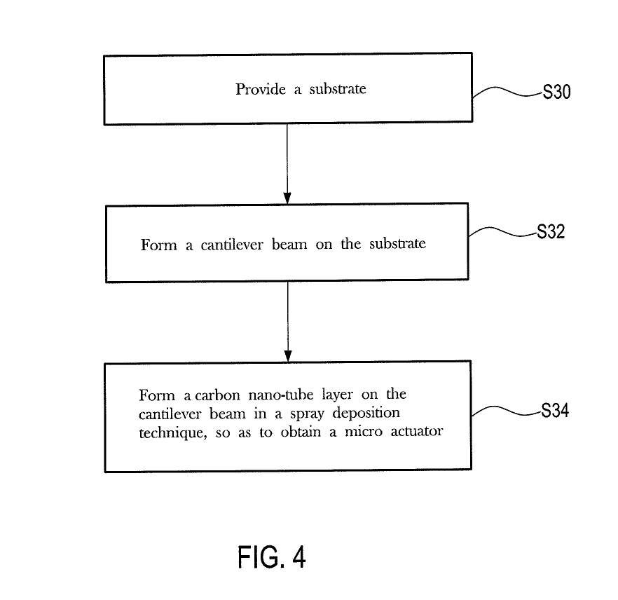

FIG. 4 is a flow chart of a method for fabricating a micro actuator according to another embodiment of the invention. As shown in FIG. 4, the method for fabricating the micro actuator includes the following steps. In Step S30, a substrate is provided. In Step S32, a cantilever beam is formed on the substrate. In Step S34, a carbon nano-tube layer is formed on the cantilever beam in a spray deposition technique, so as to obtain a micro actuator.

In this embodiment, in Step S30, the substrate of the actuator may be, but is not limited to, a glass substrate. Next, in Step S32, the cantilever beam is fabricated on the substrate in an exposure and developing method. In Step S34, the carbon nano-tube layer is formed on the cantilever beam in the spray deposition technique at a low temperature or room temperature, thereby obtaining the micro actuator. It should be noted that the low temperature of this embodiment may be slightly higher than the room temperature, for example, 85° C.

In practices, during a process of spraying the carbon nano-tube, the actuator is heated to a temperature environment of approximately 85° C., so as to accelerate vaporization of the solvent in the carbon nano-tube solution sprayed on the cantilever beam, and thus the carbon nano-tube may be more quickly deposited on the cantilever beam to form the carbon nano-tube layer. In such a temperature environment, the cantilever beam made of a polymer material may not be affected by the temperature and deteriorated.

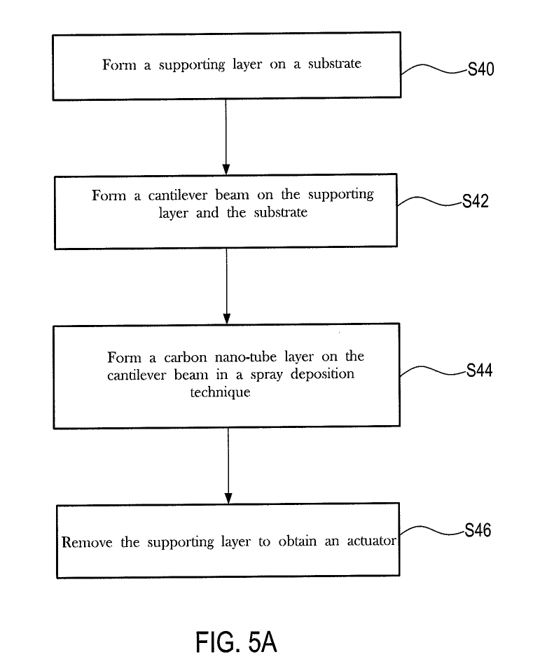

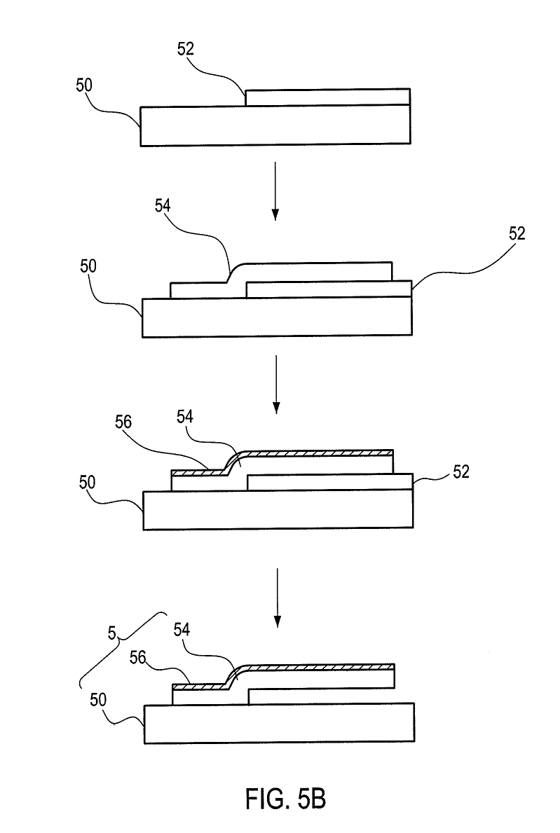

FIG. 5A is a flow chart of a method for fabricating a micro actuator according to another embodiment of the invention, and FIG. 5B is a schematic view of fabricating a micro actuator 5 by using the method for fabricating the micro actuator in FIG. 5A. As shown in FIGS. 5A and 5B, this embodiment is different from the above embodiment in that, in this embodiment, a supporting layer is formed first, and then removed after a carbon nano-tube layer is formed on a cantilever beam in a spray deposition technique.

In this embodiment, the method for fabricating the micro actuator includes the following steps. In Step S40, a supporting layer 52 is formed on a substrate 50. In Step S42, a cantilever beam 54 is formed on the supporting layer 52 and the substrate 50. In Step S44, a carbon nano-tube layer 56 is formed on the cantilever beam 54 in a spray deposition technique. In Step S46, the supporting layer 52 is removed to obtain the actuator 5. Therefore, according to this embodiment and the foregoing embodiment, the cantilever beam may be formed before the carbon nano-tube is formed in the spray deposition technique, or a leading structure may be formed first, and then removed after the carbon nano-tube is formed in the spray deposition technique, thereby obtaining the cantilever beam having the carbon nano-tube layer.

The carbon nano-tube layer is disposed on the cantilever beam of the micro actuator in the above embodiments, a light beam directly irradiates the carbon nano-tube layer to absorb optical energy and convert the optical energy to electric energy or thermal energy, so as to actuate the cantilever beam. However, in practices, if the carbon nano-tube layer is damaged by an external force, the micro actuator may lose the actuating function.

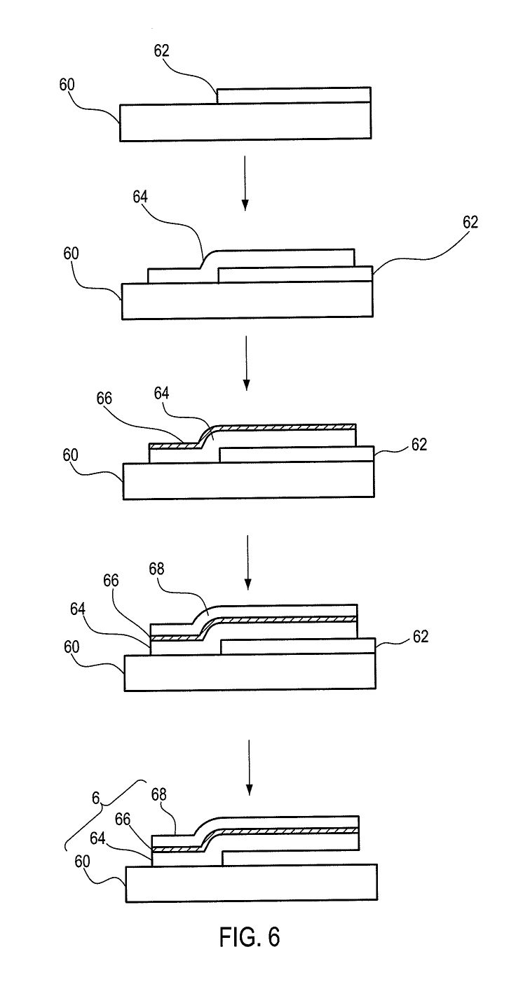

FIG. 6 is a flow chart of fabricating a micro actuator 6 according to another embodiment of the invention. As shown in FIG. 6, the micro actuator 6 of this embodiment includes a substrate 60, a cantilever beam 64, a carbon nano-tube layer 66, and a protection layer 68. The protection layer 68 is disposed on the carbon nano-tube layer 66, and the carbon nano-tube layer 66 is sandwiched between the protection layer 68 and the cantilever beam 64, thereby protecting the carbon nano-tube layer 66. In practices, the protection layer 68 may be made of, but not limited to, SU-8 polymer, and the cantilever beam 64 may be made of metal, such that the carbon nano-tube may be protected in a sandwich structure of metal/carbon nano-tube/polymer.

In this embodiment, in the method for fabricating the micro actuator 6, referring to FIG. 6, firstly, a supporting layer 62 is formed on the substrate 60. Next, the cantilever beam 64 is formed on the supporting layer 62 and the substrate 60, and the carbon nano-tube layer 66 is formed on the cantilever beam 64 in a spray deposition technique. Afterwards, the protection layer 68 is disposed on the carbon nano-tube layer 66, and a size of the structure of the cantilever beam is defined through a micro-process. Finally, the supporting layer 62 is removed to obtain the micro actuator 6. In practice, the protection layer 68 may be, but is not limited to, disposed on the carbon nano-tube layer 66 in a spin coating manner.

To sum up, the micro actuator of the invention is formed on the carbon nano-tube layer in the spray deposition technique, and as compared with the prior art, the temperature environment required by the process of the spray deposition technique is low, and the plasma is not required to assist the growth of the carbon nano-tube, such that the micro actuator of the invention may be made of a thermolabile material or a material having a weak structure, for example, a polymer material, thereby increasing the application of the micro actuator. Further, as compared with the carbon nano-tube growing method in the manner of thermal growth or plasma assisted growth, the spray deposition method is more convenient. Therefore, the micro actuator and the micro actuator system of the invention have a lower production cost.

Through the detailed description of the preferred embodiments, features and spirits of the invention are illustrated more clearly, and the scope of the invention is not limited to the preferred embodiments. On the contrary, the objective of the invention is to cover various variations and equivalent changes in the scope of the appended claims. Therefore, the scope of the appended claims of the invention should be construed in the broadest sense according to the above description, so as to cover all possible variations and equivalent changes.

What is claimed is:

1. A micro actuator system, comprising:
a micro actuator, comprising:
a substrate;
a cantilever beam, having a connection portion connected to the substrate; and
a carbon nano-tube layer, disposed on the cantilever beam in a spray deposition technique; and
a light beam generator, for generating a light beam for irradiating the connection portion of the cantilever beam,
wherein when the light beam generator generates the light beam to irradiate the connection portion of the cantilever beam, the carbon nano-tube layer drives the cantilever beam to be deformed towards a first direction.

2. The micro actuator system according to claim 1, wherein the cantilever beam is made of a polymer material.

3. The micro actuator system according to claim 1, wherein the micro actuator further comprises:
a protection layer, disposed on the carbon nano-tube layer.

4. The micro actuator system according to claim 3, wherein the cantilever beam is made of a metal material.

5. The micro actuator system according to claim 1, wherein the light beam generated by the light beam generator is an ultraviolet laser.

6. The micro actuator system according to claim 1, wherein the light beam generated by the light beam generator is an infrared laser.

7. The micro actuator system according to claim 1, wherein the carbon nano-tube layer comprises a multi-layer carbon nano-tube.

8. The micro actuator system according to claim 1, wherein when the light beam generator stops generating the light beam, the cantilever beam is restored to an original position along the first direction.

9. The micro actuator system according to claim 1, further comprising a control circuit connected to the light beam generator and capable of controlling the light beam generator to generate the light beam.

10. The micro actuator system according to claim 1, wherein the substrate is a glass substrate.

11. A micro actuator, comprising:
a substrate;
a cantilever beam, having a connection portion connected to the substrate; and
a carbon nano-tube layer, disposed on the cantilever beam in a spray deposition technique.

12. The micro actuator according to claim 11, wherein the cantilever beam is made of a polymer material.

13. The micro actuator according to claim 11, further comprising
a protection layer, disposed on the carbon nano-tube layer.

14. The micro actuator according to claim 13, wherein the cantilever beam is made of a metal material.

15. The micro actuator according to claim 11, wherein the carbon nano-tube layer comprises a multi-layer carbon nano-tube.

16. The micro actuator according to claim 11, wherein the substrate is a glass substrate.

17. A method for fabricating a micro actuator, comprising:
providing a substrate;
forming a cantilever beam on the substrate; and
forming a carbon nano-tube layer on the cantilever beam in a spray deposition technique, so as to obtain the micro actuator.

18. The method for fabricating the micro actuator according to claim 17, wherein the step of forming the carbon nano-tube layer on the cantilever beam in the spray deposition technique is performed at a low temperature or a room temperature.

19. The method for fabricating the micro actuator according to claim 17, wherein the step of forming the cantilever beam on the substrate is performed by using an exposure and developing method.

20. The method for fabricating the micro actuator according to claim 17, further comprising:
forming a protection layer on the carbon nano-tube layer.
